(19) United States
(12) Patent Application Publication
(10) Pub. No.: US 2018/0320885 A1
(43) Pub. Date: Nov. 8, 2018

(54) LIGHT MODULE HAVING A HEATSINK CRIMPED AROUND A LENS, AND A METHOD FOR CRIMPING A HEAT SINK AROUND A LENS OF A LIGHT MODULE

(71) Applicant: Flex Ltd., Singapore (SG)

(72) Inventors: Jordon Musser, Dallas, TX (US); Chris Stratas, Burlingame, CA (US)

(21) Appl. No.: 15/687,012

(22) Filed: Aug. 25, 2017

Related U.S. Application Data
(60) Provisional application No. 62/502,026, filed on May 5, 2017.

(51) Int. Cl. F21V 31/00; F21V 15/015; F21V 17/10; F21V 5/04; F21V 29/76; F21V 29/89; F21V 19/00; F21V 29/75

(52) U.S. Cl. CPC F21V 31/005; F21V 15/015; F21V 17/104; F21V 5/048; H05K 1/0203; F21V 29/89; F21V 19/0045; F21V 29/75; H05K 2201/10106; F21V 29/763

(57) ABSTRACT

A device is provided that includes a lens for covering a printed circuit board having a light emitting diode. The lens forms an arc in a lateral cross-section and includes two first edges at the ends of the arc. The arc spans a width of the printed circuit board and defines a space between the lens and the printed circuit board. The device also includes a heatsink adapted to couple to the printed circuit board and which extends substantially the width and the length of the printed circuit board. The heatsink includes two second edges along the length of the printed circuit board. One of the edges of the lens is positioned in a channel on one of the second edges of the heatsink, and the channel is crimped. A method is provided that includes providing a crimping a channel around a lens.

### BACKGROUND

### 1. Technical Field

The present disclosure relates to lighting fixtures. More particularly, the present invention relates to a light module having a heatsink crimped around a lens to prevent ingress of dust and liquids, and a method for making a light module having a heatsink crimped around a lens.

### 2. Discussion of Related Art

Lighting, also referred to as artificial lights, is important in commercial and residential environments. Indoor lighting is critical for use of interior spaces during day and night. Outdoor lighting enables the use of outdoor spaces safely during periods of darkness. Lights can be expensive to install and operate. Light-emitting diode (LED) lights can reduce the costs of installing and operating lights due to their long useful operating life and relatively low energy usage.

LED lights operate better, and last longer, when maintained dry and clean. However, lights for large interior spaces often confront dirt and dust, and additionally may risk exposure to water via humidity or roof leaks. Outdoor lighting is even more likely to experience dirt, dust and water. Therefore, there is a need for a light fixture that safely and economically seals an enclosure around an LED light, to prevent ingress of dirt, dust, and moisture.

### SUMMARY

Provided in accordance with the present disclosure is a device that includes a lens for covering a printed circuit board having a light emitting diode. The lens forms an arc in a lateral cross-section and includes two first edges at the ends of the arc. The arc spans a width of the printed circuit board and defines a space between the lens and the printed circuit board. The lens extends along the two first edges substantially a length of the printed circuit board. The device also includes a heatsink adapted to couple to the printed circuit board and which extends substantially the width and the length of the printed circuit board. The heatsink includes two second edges along the length of the printed circuit board. One of the first edges of the lens is positioned in a channel on one of the second edges of the heatsink, and the channel is crimped.

In an aspect of the present disclosure, the first edges may be two first edges of the lens, and the channel may be two channels. The second edges may be two second edges of the heatsink and the two first edges of the lens may be received in the two channels on respective ones of the two second edges of the heatsink. The two channels may be crimped.

In another aspect of the present disclosure, the crimping forms a seal between the heatsink and the lens at the channel. The crimping may provide ingress protection from dust and liquids. Sealant may be provided in the channel to improve the seal when the at least one channel is crimped.

In additional aspects of the present disclosure, the heatsink may include extruded aluminum. The crimping may include mechanically deforming the aluminum heatsink to seal around the lens. The lens may include translucent plastic.

In another aspect of the present disclosure, the printed circuit board is planar having the length in a longitudinal direction. The heatsink may be coupled to the printed circuit board by positioning a third edge of the printed circuit board in a further channel on a second edge of the heatsink. The further channel may be crimped.

In still further aspects of the present disclosure, the printed circuit board may be interposed between the heatsink and the lens. The printed circuit board, the heatsink, and the lens may form in combination a light module. The device may include another light module and two endcaps arranged on opposing ends of the two light modules. The two endcaps may be mechanically coupled to the two light modules and may provide a second seal to inhibit ingress from ends of the two light modules to the printed circuit board.

In other aspects of the present disclosure, the heatsink may form a base of the arc in the lateral cross-section. The base may span substantially the width of the printed circuit board and may be substantially parallel to the printed circuit board.

A method according to present disclosure includes providing a lens for covering a printed circuit board having at least one light emitting diode. The lens forms an arc in a lateral cross-section, and includes two first edges at the ends of the arc. The arc spans a width of the printed circuit board and defines a space between the lens and the printed circuit board. The lens extends along the two first edges substantially a length of the printed circuit board. The method also includes providing a heatsink adapted to couple to the printed circuit board. The heatsink extends substantially the width and the length of the printed circuit board, and includes two second edges along the length of the printed circuit board. The method further includes positioning a first edge of the lens in a channel on a second edge of the heatsink, and crimping the channel.

In an aspect of the present disclosure, the first edge is two first edges of the lens, the channel is two channels, and the second edge is two second edges of the heatsink. The positioning operation may be of the first edges of the lens in two channels on two second edges of the heatsink, and the crimping operation may be of the two channels.

In an aspect of the present disclosure, the crimping operation may include forming a seal between the heatsink and the lens at the channel, and may include providing ingress protection from dust and liquids.

In a further aspect of the present disclosure, the method may include providing sealant in the channel to improve the seal, which may be performed before, during, or after the crimping operation.

The heatsink may include extruded aluminum, and the crimping operation may include mechanically deforming the aluminum heatsink to seal around the lens.

In another aspect of the present disclosure, the printed circuit board may be planar having the length in a longitudinal direction, and the method may include positioning a third edge of the printed circuit board in a further channel on a second edge of the heatsink. The method may further include crimping the further channel of the heatsink around the third edge of the printed circuit board. The further crimping operation and the crimping operation may be performed substantially simultaneously.

In still further aspects of the present disclosure, the method may include positioning the printed circuit board between the heatsink and the lens. The printed circuit board, the heatsink, and the lens may form in combination a first light module. The method may include providing at least one second light module, and arranging two endcaps on opposing ends of the first and second light modules. The two endcaps may be mechanically coupled to the first and second light modules and provide a second seal to inhibit ingress from ends of the first and second light modules to the printed circuit board.

Further, to the extent consistent, any of the aspects described herein may be used in conjunction with any or all of the other aspects described herein.

### BRIEF DESCRIPTION OF THE DRAWINGS

Various aspects and features of the present disclosure are described herein below with references to the drawings.

FIG. 1 is a perspective view of an exemplary embodiment of a light fixture according to the present technology.

FIG. 2 is an exploded view of an exemplary embodiment of a light fixture according to the present technology.

FIG. 3 is a diagram illustrating an exploded view of a light module according to an exemplary embodiment of the present technology.

FIG. 4 is a diagram illustrating a cross-sectional view of a lens for a light module according to an exemplary embodiment of the present technology.

FIGS. 5A-5B are diagrams illustrating cross-sectional views of light modules before a heatsink is crimped around a lens and after the heatsink is crimped around the lens, according to an exemplary embodiment of the present technology.

FIGS. 6A-6B are diagrams illustrating cross-sectional views of the crimp shown in FIGS. 5A-5B according to an exemplary embodiment of the present technology.

FIG. 7 is a flow chart illustrating an exemplary method according to an exemplary embodiment of the present technology.

### DETAILED DESCRIPTION

The present disclosure is directed, in part, to devices and methods for providing artificial light. In particular, the present technology addresses problems associated with protecting lighting fixtures by safely and economically sealing an enclosure around an LED light. A light module is described having a heatsink crimped around a lens to prevent ingress of dust and liquids, and a method for making a light module having a heatsink crimped around a lens.

Crimping the heatsink around a lens includes mechanically deforming the aluminum heatsink to seal around the lens. Additionally, in a previous or simultaneous operation, the heatsink may be crimped around the LED PCB. Mechanically deforming the aluminum heatsink to capture and press the PCB eliminates use of thermally conductive adhesive tape by attaching the PCB directly to the extruded aluminum heatsink.

Light modules (also referred to as light fixtures, fixtures, or modules) are provided. Light modules may also include a light-emitting diode (LED) pattern on a printed circuit board (PCB), thermally conductive tape, and/or an aluminum heatsink. Light fixtures according to the present technology may include any number of LEDs patterned on a PCB, arranged in series and/or parallel strings.

Light modules according to the present technology may include a heatsink designed for LED modules that includes a custom, optimized aluminum extruded heatsink to efficiently cool LEDs using natural convection.

Light modules according to the present technology may also include a custom extruded plastic lenses with engineered optics to provide maximum light transmission and provide various types of light distribution (for example, wide and aisle distributions).

Modular wire guards may be provided that include steel wire guards for protecting the lenses. The module wire guards may be designed to protect only one module each, and in this manner, the modular design may be used to fit any number of modules. In this manner, the same wire guard may be used in light fixtures having two, four, six, or any number of light modules per fixture.

Embodiments of the present disclosure are now described in detail with reference to the drawings in which like reference numerals designate identical or corresponding elements in each of the several views. Additionally, in the drawings and in the description that follows, terms such as front, rear, upper, lower, top, bottom, and similar directional terms are used simply for convenience of description and are not intended to limit the disclosure. In the following description, well-known functions or constructions are not described in detail to avoid obscuring the present disclosure in unnecessary detail.

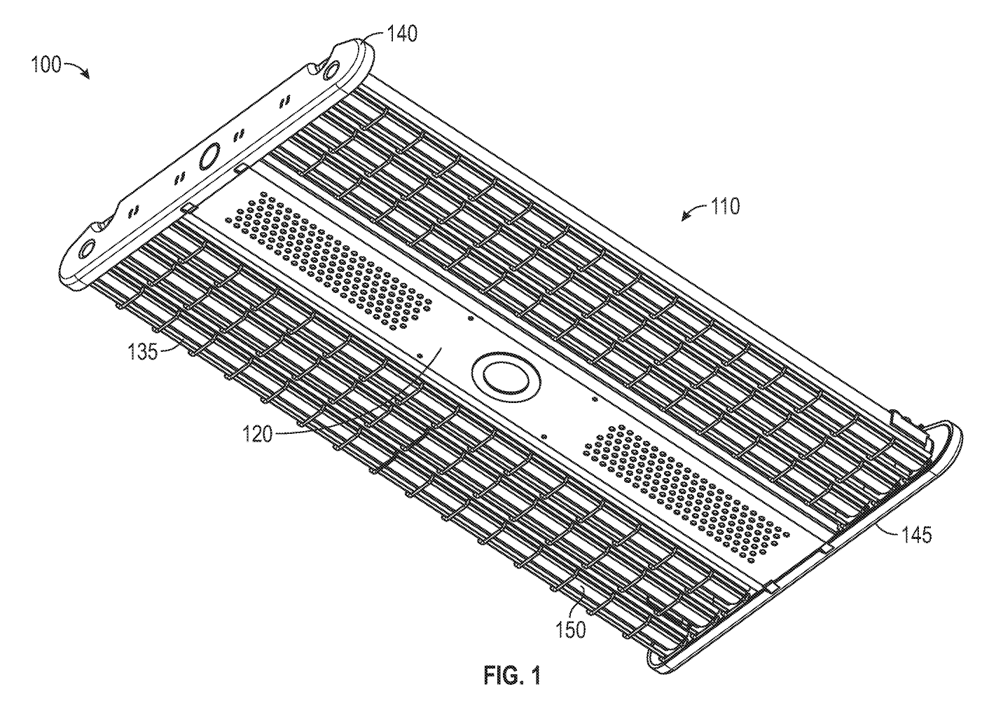

With reference to FIG. 1, light fixture 100 is shown in a perspective view. Light fixture 100 includes light modules 110. As shown in FIG. 1, light fixture 100 includes six light modules, each being linear and with three light modules arranged on one side of wireway 120, and three light modules arranged on the other side of wireway 120. Alternatively, light fixture 100 may include two or four light modules, or more, which may be arranged in equal numbers on either side of wireway 120. In still further exemplary embodiments, the number of light modules may not be evenly divided on either side of wireway 120, and light fixture 100 may include an odd number of light modules. Arranged on opposing ends of light modules 110 and wireway 120 are first endcap 140 and second endcap 145. Light modules in light fixture 100 include, or are provided with, wire guards to protect lights and or lenses of the light modules from impacts without excessively impairing the illumination provided by the light modules. As shown in FIG. 1, wire guard 150 is a modular wire guard arranged on outer light module 135.

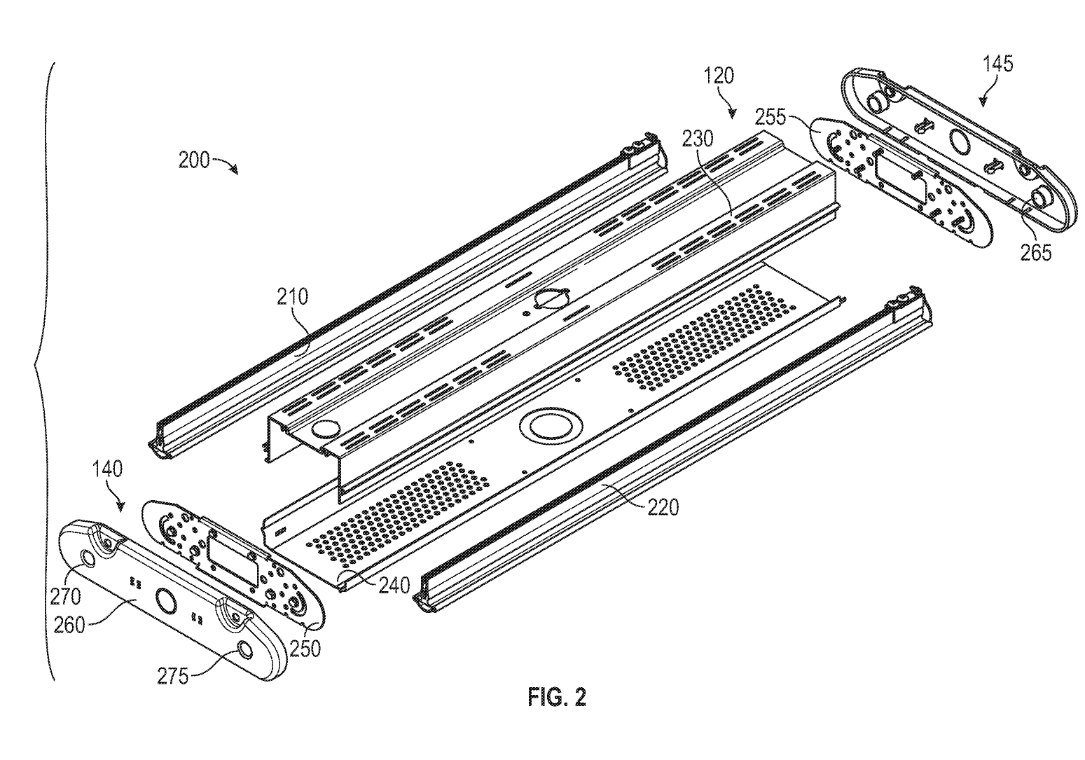

FIG. 2 is an exploded view of light fixture 200 according to the present technology. Light fixture 200 includes two light modules, namely first outer light module 210 and second outer light module 220. Wireway 120 is shown in FIG. 2 disassembled into upper wireway section 230 and lower wireway section 240. Upper wireway section 230 and lower wireway section 240 may combine to form wireway 120, including an interior space to accommodate wires and/or drivers for powering LED lights in first light module 210 and second outer light module 220. Wireway 120 may also function as a heatsink for the LED drivers. Wireway 120 may permit direct access to electrical components housed therein upon removal of lower wireway section 240 and/or upper wireway section 230.

First endcap 140 is shown in FIG. 2 disassembled into first inner endcap 250 and first outer endcap 260. Second endcap 145 is also shown in FIG. 2 disassembled into second inner endcap 255 and second outer endcap 265. First inner endcap 250 and second inner endcap 255 may attach to, or alternatively, function as mounting plates for, opposite ends of first outer light module 210, second outer light module 220, and wireway 120. In this manner, the relative distances and directions between first outer light module 210, second outer light module 220, and wireway 120 with respect to each other may be fixed.

First outer endcap 260 and second outer endcap 265 may be composed of plastic or any other appropriate material, and may provide an aesthetic appearance and/or operate to protect the wiring of the module assemblies.

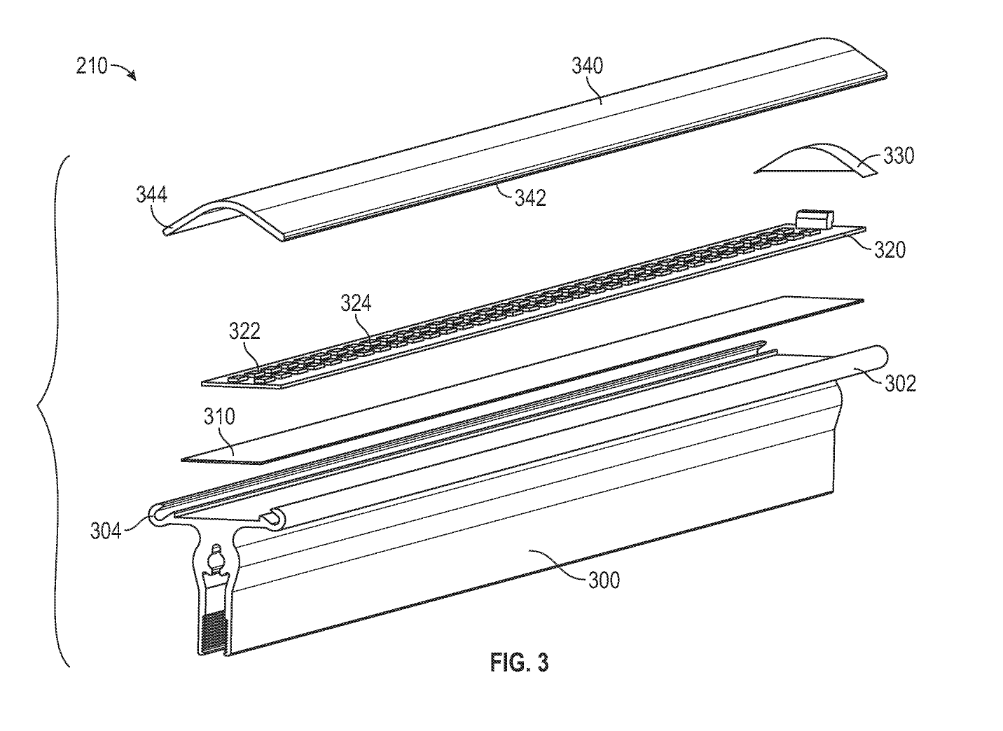

FIG. 3 is a diagram illustrating an exploded view of light module 210 according to an exemplary embodiment of the present technology. Shown in FIG. 3 is heatsink 300, which may be formed by extruding aluminum, and thermal tape 310, which may be thermally conductive adhesive tape used to attach PCB assembly 320 to heatsink 300. Heatsink 300 includes two edges 302, 304. In alternative exemplary embodiments, thermal tape 310 may not be used, and PCB assembly 320 may be attached to heatsink 300 by any appropriate method. For example, heatsink 300 may be attached to PCB assembly 320 by crimping a channel formed from heatsink 300 that receives an edge of PCB assembly 320. PCB assembly 320 may include LEDs and connectors on a printed circuit board, and may have a short edge 322 defining a width, and a long edge 324 defining a length. At an end of PCB assembly 320 may be positioned connector cover 330, which may be a flame retardant cover for a connector on PCB assembly 320. Covering the length of PCB assembly 320 may be lens 340, which may be an extruded plastic lens, or a lens made of any other appropriate material. Lens 340 includes two edges 342, 344, defining an arc between them.

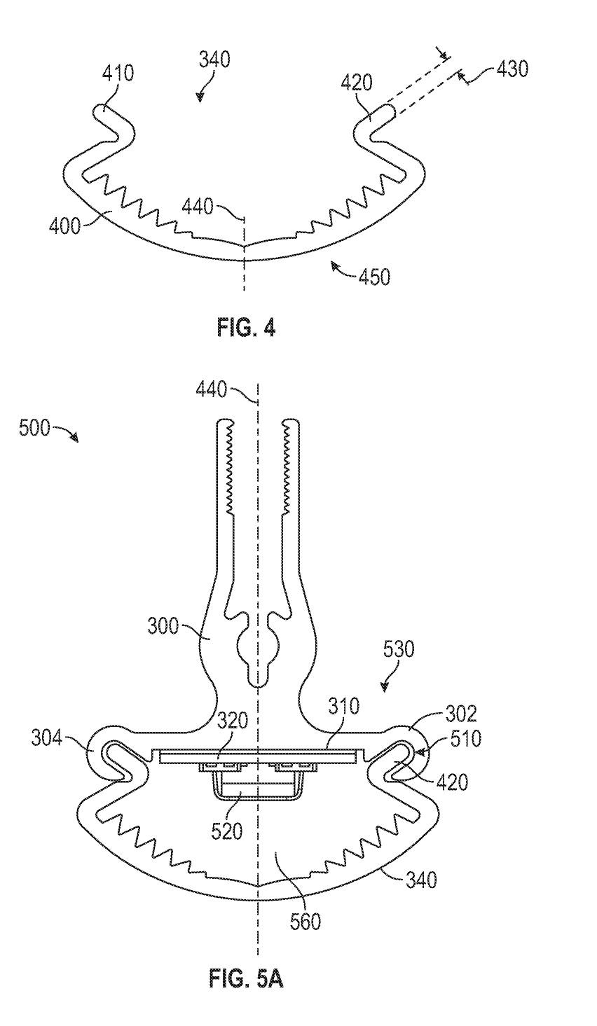

FIG. 4 is a diagram illustrating a cross-sectional view of lens 340 for a light module according to an exemplary embodiment of the present technology. Lens 340 may be transparent or translucent, and may include plastic or any other appropriate material and may form a lens arc 450, also referred to as an arc. Lens 340 may include illumination region 400, which may be positioned to direct light from an LED to an area requiring illumination. Illumination region 400 may include center line 440, which may bisect the cross-section of lens 340. Lens 340 may also include first flange 410 (also referred to as an arm) and second flange 420, which may each have thickness 430. First and second flange 410, 420 may be designed to be received in a channel formed in a heatsink, which may be of a width slightly larger than thickness 430. In this manner, the heatsink may be crimped during assembly to form a seal with lens 340.

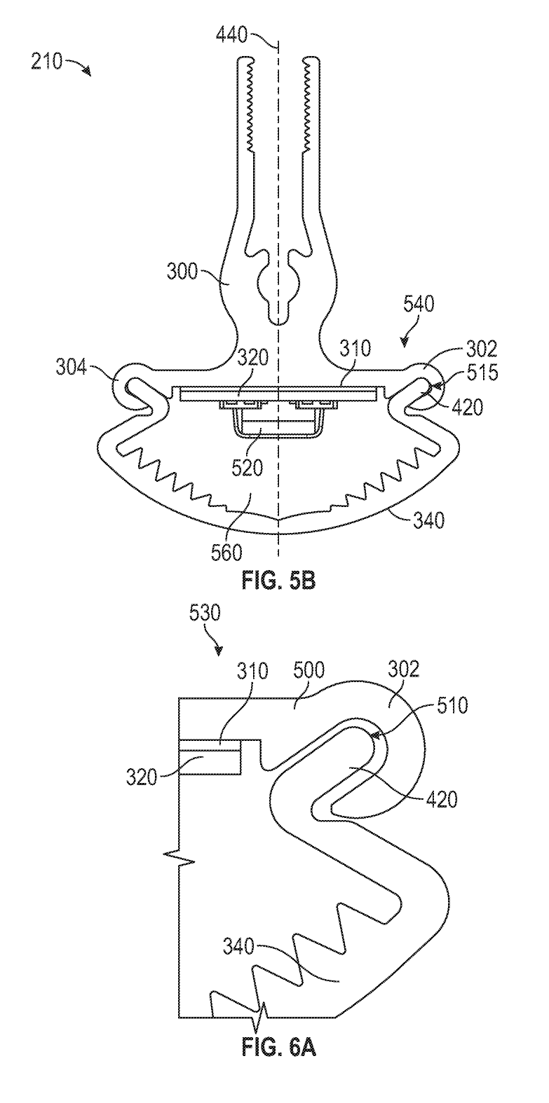

FIG. 5A illustrates a cross-sectional view of light module 500 in a partially-assembled condition, with center line 440. In particular, FIG. 5A shows light module 500 before heatsink 300 is crimped around lens 340. Heatsink 300 is shown in FIG. 5A with PCB assembly 320 mounted thereon, and including two edges 302, 304. PCB assembly 320 partially occupies space 560 between lens 340 and heatsink 300. Thermal tape 310 may be used to attach PCB assembly 320 to heatsink 300. Alternatively, heatsink 300 may be crimped around PCB assembly 320, and/or PCB assembly 320 may be attached to heatsink 300 by any appropriate method. PCB assembly 320 is shown in FIG. 5A with LED 520, which may be one of several LEDs mounted on PCB assembly 320, and connected in series or parallel. Lens 340 covers and protects LED 520 from impacts. Additionally, a wireguard may be employed to protect lens 340, and consequently also LED 520 from impacts. Lens 340 includes second flange 420, which is positioned in uncrimped channel 510. Second flange 420 and uncrimped channel 510 may together form pre-crimp coupling 530. Additionally, a sealant may be introduced into uncrimped channel 510, either before, during or after positioning second flange 420 in uncrimped channel 510.

FIG. 5B illustrates a cross-sectional view of light module 210, which may be light module 500 shown in FIG. 5A after a crimping operation has been performed. In particular, FIG. 5B shows light module 210 after heatsink 300 is crimped around lens 340, and includes center line 440. Heatsink 300 is shown in FIG. 5B with PCB assembly 320 mounted thereon, and including two edges 302, 304. PCB assembly 320 partially occupies space 560 between lens 340 and heatsink 300. Thermal tape 310 may be used to attach PCB assembly 320 to heatsink 300. Alternatively, heatsink 300 may be crimped around PCB assembly 320, and/or PCB assembly 320 may be attached to heatsink 300 by any appropriate method. PCB assembly 320 is shown in FIG. 5A with LED 520, which may be one of several LEDs mounted on PCB assembly 320, and connected in series or parallel. Lens 340 covers and protects LED 520, and since heatsink 300 is crimped around lens 340, LED 520 is also protected from the ingress of liquids and dust by the combination of lens 340 and heatsink 300. Additionally, a wireguard may be employed to protect lens 340, and consequently also LED 520, from impacts. Lens 340 includes second flange 420, which is positioned in crimped channel 515. Second flange 420 and crimped channel 515 may together form crimp coupling 540.

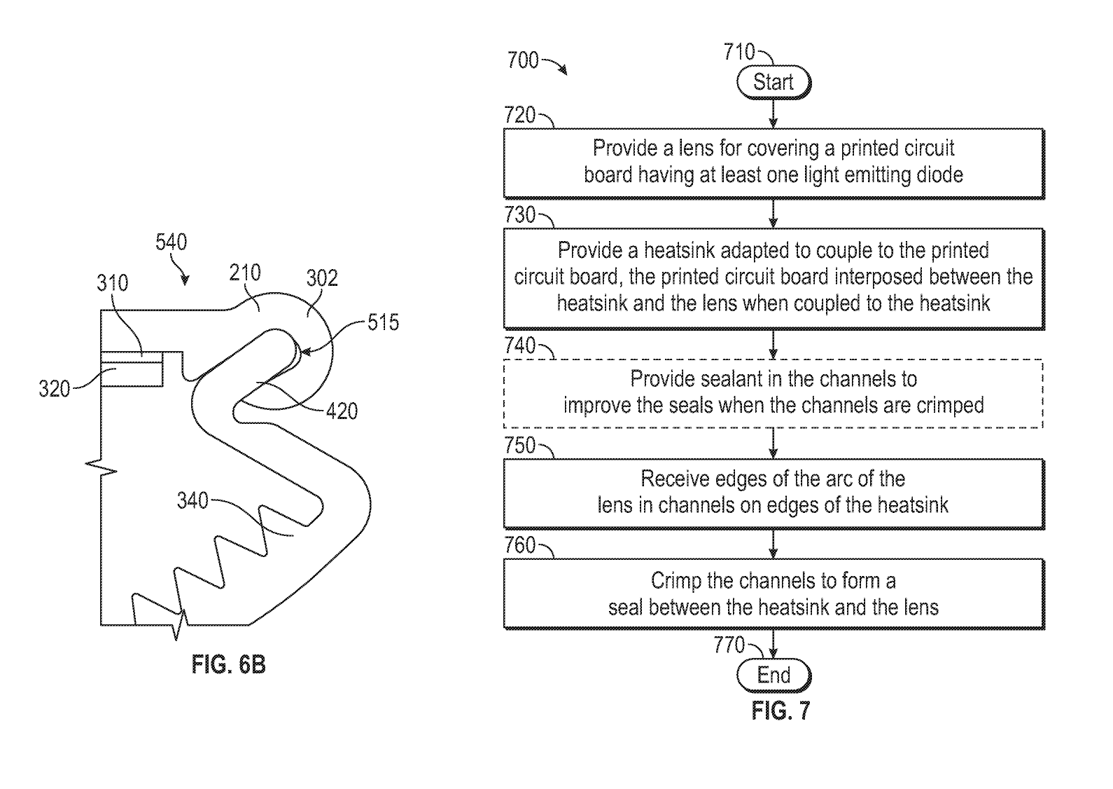

FIG. 6A illustrates a cross-sectional view of pre-crimp coupling 530 of a light module before heatsink 500 is crimped around lens 340. FIG. 6A shows PCB assembly 320 mounted on heatsink 500 using thermal tape 310 tape. Additionally or alternatively, PCB assembly 320 may be mounted on heatsink 500 by crimping, or any other appropriate method. Lens 340 includes second flange 420, which is received in uncrimped channel 510 to form pre-crimp coupling 530. Uncrimped channel 510 is arranged on edge 302 of heatsink 300. As shown in FIG. 6A, an airgap exists around second flange 420 in uncrimped channel 510. Therefore, pre-crimp coupling 530 may not protect PCB assembly 320 from the ingress of liquids and dust. Additionally, a sealant may be introduced into uncrimped channel 510, either before, during or after receiving second flange 420 in uncrimped channel 510.

FIG. 6B illustrates a cross-sectional view of crimp coupling 540 of a light module after heatsink 300 is crimped around lens 340. FIG. 6B shows PCB assembly 320 mounted on heatsink 300 using thermal tape 310 tape. Additionally or alternatively, PCB assembly 320 may be mounted on heatsink 300 by crimping, or any other appropriate method. Lens 340 includes second flange 420, which is received in crimped channel 515. Crimped channel 515 is arranged on edge 302 of heatsink 300. During manufacturing of the light module, pre-crimp coupling 530 may be mechanically deformed to form crimp coupling 540. As shown in FIG. 6B, second flange 420 couples tightly to crimped channel 515. Therefore, crimp coupling 540 protects PCB assembly 320 from the ingress of liquids and dust.

FIG. 7 is a flow chart illustrating exemplary method 700 according to an exemplary embodiment of the present technology, in which optional steps are shown with broken lines. Method 700 begins at start circle 710 and proceeds to operation 720, which indicates to provide a lens for covering a printed circuit board having at least one light emitting diode. From operation 720, the flow in method 700 proceeds to operation 730, which indicates to provide a heatsink adapted to couple to the printed circuit board. The printed circuit board is interposed between the heatsink and the lens when coupled to the heatsink. From operation 730, the flow in method 700 proceeds to optional operation 740, which indicates to provide sealant in the channels to improve the seals when the channels are crimped. From optional operation 740, the flow in method 700 proceeds to operation 750, which indicates to receive edges of the arc of the lens in channels on edges of the heatsink. From operation 750, the flow in method 700 proceeds to operation 760, which indicates to crimp the channels to form a seal between the heatsink and the lens. From operation 760, the flow in method 700 proceeds to end circle 770. The order of operations shown in FIG. 7 is exemplary only, and operations may be performed in a different order. For instance, optional operation 740 may be performed after operation 750, or even after operation 760 in some exemplary embodiments.

Detailed embodiments of such devices, systems incorporating such devices, and methods using the same are described above. However, these detailed embodiments are merely examples of the disclosure, which may be embodied in various forms. Therefore, specific structural and functional details disclosed herein are not to be interpreted as limiting but merely as a basis for the claims and as a representative basis for allowing one skilled in the art to variously employ the present disclosure in virtually any appropriately detailed structure. The scope of the technology should therefore be determined with reference to the appended claims along with their full scope of equivalents.

What is claimed:

1. A device comprising:
a lens for covering a printed circuit board having at least one light emitting diode, the lens forming an arc in a lateral cross-section, the lens including at least two first edges at the ends of the arc, the arc spanning at least a width of the printed circuit board and defining a space between the lens and the printed circuit board, the lens extending along the at least two first edges substantially a length of the printed circuit board; and
a heatsink adapted to couple to the printed circuit board, the heatsink extending substantially the width and the length of the printed circuit board, the heatsink including at least two second edges along the length of the printed circuit board, at least one of the first edges of the lens being positioned in at least one channel on at least one of the second edges of the heatsink, the at least one channel being crimped.

2. The device of claim 1, wherein:
the at least one of the first edges is at least two first edges of the lens;
the at least one channel is at least two channels;
the at least one of the second edges is at least two second edges of the heatsink; and
the at least two first edges of the lens being received in the at least two channels on respective ones of the at least two second edges of the heatsink, the at least two channels being crimped.

3. The device of claim 1, wherein the crimping forms a seal between the heatsink and the lens at the at least one channel.

4. The device of claim 3, wherein the crimping provides ingress protection from dust and liquids.

5. The device of claim 3, wherein sealant is provided in the at least one channel to improve the seal when the at least one channel is crimped.

6. The device of claim 1, wherein the heatsink comprises extruded aluminum.

7. The device of claim 6, wherein the crimping comprises mechanically deforming the aluminum heatsink to seal around the lens.

8. The device of claim 1, wherein the lens comprises translucent plastic.

9. The device of claim 1, wherein:
the printed circuit board is planar having the length in a longitudinal direction; and
the heatsink is coupled to the printed circuit board by positioning at least one third edge of the printed circuit board in at least one further channel on at least one of the second edges of the heatsink, the at least one further channel being crimped.

10. The device of claim 1, further comprising:
the printed circuit board interposed between the heatsink and the lens, the printed circuit board, the heatsink, and the lens forming in combination a first light module;
at least one second light module; and
two endcaps arranged on opposing ends of the first and second light modules, the two endcaps being mechanically coupled to the first and second light modules and providing a second seal to inhibit ingress from ends of the first and second light modules to the printed circuit board.

11. The device of claim 1, wherein:
the heatsink forms a base of the arc in the lateral cross-section; and
the base spans substantially the width of the printed circuit board and is substantially parallel to the printed circuit board.

12. A method for lighting, comprising:
providing a lens for covering a printed circuit board having at least one light emitting diode, the lens forming an arc in a lateral cross-section, the lens including at least two first edges at the ends of the arc, the arc spanning at least a width of the printed circuit board and defining a space between the lens and the printed circuit board, the lens extending along the at least two first edges substantially a length of the printed circuit board;
providing a heatsink adapted to couple to the printed circuit board, the heatsink extending substantially the width and the length of the printed circuit board, the heatsink including at least two second edges along the length of the printed circuit board;
positioning at least one of the first edges of the lens in at least one channel on at least one of the second edges of the heatsink; and
crimping the at least one channel.

13. The method of claim 12, wherein:
the at least one of the first edges is at least two first edges of the lens;
the at least one channel is at least two channels;
the at least one of the second edges is at least two second edges of the heatsink;
the positioning operation is of at least two of the first edges of the lens in at least two channels on the at least two second edges of the heatsink; and
the crimping operation is of the at least two channels.

14. The method of claim 12, wherein the crimping operation comprises forming a seal between the heatsink and the lens at the at least one channel.

15. The method of claim 12, wherein the crimping operation comprises providing ingress protection from dust and liquids.

16. The method of claim 12, further comprising providing sealant in the at least one channel to improve the seal, the providing sealant operation being performed one of:
before, during, and after the crimping operation is performed.

17. The method of claim 12, wherein
the heatsink comprises extruded aluminum; and
the crimping operation comprises mechanically deforming the aluminum heatsink to seal around the lens.

18. The method of claim 12, wherein the printed circuit board is planar having the length in a longitudinal direction, and further comprising:
positioning at least one third edge of the printed circuit board in at least one further channel on at least one of the second edges of the heatsink; and
further crimping the at least one further channel of the heatsink around the at least one third edge of the printed circuit board, the further crimping operation and the crimping operation being performed substantially simultaneously.

19. The method of claim 12, further comprising:
positioning the printed circuit board between the heatsink and the lens, the printed circuit board, the heatsink, and the lens forming in combination a first light module;
providing at least one second light module; and
arranging two endcaps on opposing ends of the first and second light modules, the two endcaps being mechanically coupled to the first and second light modules and providing a second seal to inhibit ingress from ends of the first and second light modules to the printed circuit board.
